(19) United States
(12) Patent Application Publication
(10) Pub. No.: US 2012/0130655 A1
(43) Pub. Date: May 24, 2012

(54) DEGRADATION MONITORING METHOD AND DEGRADATION MONITORING DEVICE FOR ELECTRICITY STORAGE DEVICE

(75) Inventors: Kenro MITSUDA, Tokyo (JP); Akihisa Yoshimura, Tokyo (JP); Shoichi Kitamura, Tokyo (JP); Takuto Yano, Tokyo (JP)

(73) Assignee: MITSUBISHI ELECTRIC CORPORATION, Chiyoda-ku (JP)

(21) Appl. No.: 13/298,988

(22) Filed: Nov. 17, 2011

(30) Foreign Application Priority Data
Nov. 24, 2010 (JP) 2010-261467
Oct. 5, 2011 (JP) 2011-220932

(51) Int. Cl. G06F 19/00; G01R 31/36

(52) U.S. Cl. 702/58

(57) ABSTRACT

A damage calculation unit (2, 3) performs: acquiring a charge current value, a charge period, and a representative temperature of the electricity storage device while the electricity storage device is being charged, calculating a cycle damage number for representative temperature based on the obtained values, and integrating the cycle damage number for representative temperature; and acquiring a representative temperature of the electricity storage device in at least an operation state out of the operation state and a storage state, and an elapsed period at the representative temperature, calculating a calendar damage number based on acquired values of the representative temperature and the elapsed period, and integrating the calendar damage number.

### BACKGROUND OF THE INVENTION

1. Field of the Invention

The present invention relates to a degradation monitoring method and a degradation monitoring device for an electricity storage device used for an electricity storage system incorporating an electricity storage device, and for monitoring a damage on the electricity storage device (degree of degradation of the electricity storage device).

2. Description of the Related Art

It is a major problem to know what damage is caused on the electricity storage device by charge/discharge, storage temperature, and the like, and how long the electricity storage device can be used in the electricity storage system using the electricity storage devices.

In recent years, there are trends of a battery-leasing electric vehicle where a discharged battery (electricity storage device) is removed from the electric vehicle, and another charged battery is installed on the electric vehicle, and a reuse of batteries once used for a travel application such as an electric vehicle for stationary applications (so-called smart grid) such as output smoothing of solar cells. Needs for quantitatively and easily evaluating the damages on the batteries are rapidly increasing according to these trends.

On this occasion, the damage of the battery largely depends on the number of times of charge/discharge. The upper limit of the number of charge/discharge is limited to approximately 300 times on a conventional battery, and the number of the charge/discharge is a major dominant factor of the damage. A “rechargeable battery pack having function of automatically calculating and displaying number of times of charge” is disclosed in FIG. 1 of Japanese Patent Application Laid-open No. Hei 3-159526, for example. In the conventional device as disclosed in Japanese Patent Application Laid-open No. Hei 3-159526, the voltage level of the battery is monitored, and after detecting that the voltage level of the battery has fallen below a certain set value, when it is detected that the battery voltage reaches a charge end voltage value by a charge operation, a counter is incremented by one each time the charge end is detected.

On this occasion, it is only necessary to simply recognize the number of times of charge/discharge for an application in which a battery is fully charged using a charger after the battery becomes empty, and this procedure is repeated. However, non-periodical charge is carried out by a regeneration operation by a motor and solar cells, and the charge/discharge is repeated not at a state of charge (SOC) close to 100% but at an SOC close to 50%, for example, for the stationary application to the electric vehicle, the output smoothing of the solar cell, and the like. Therefore, for the stationary application, it has been impossible to determine the damage of the battery merely from the number of times of charge.

Moreover, it is known that the life largely varies depending on a swing (width) of the SOC for the lead-acid battery, the nickel-metal hydride battery, the lithium-ion battery, and the like used for the electric vehicle, the hybrid vehicle, and the like. Masakazu Sasaki, Proceedings of 2008 Annual Conference of Institute of Electrical Engineers of Japan, Industry Applications Society, 2-04-4, II-205 (2008), for example, illustrates a relationship between the swing (width) of the SOC and the possible cycle number of charge/discharge, and illustrates a fact that the possible cycle number of charge/discharge increases exponentially as the swing (width) of the SOC decreases from 100 to several % for any of these batteries. It is thus important to recognize the swing (width) of the SOC.

On this occasion, it is known that the battery has calendar life, in which the battery degrades more as the temperature of the operation environment/storage environment is high even when the charge/discharge is not carried out, and it is also necessary to recognize the calendar life in order to more precisely recognize the damage on the battery.

Moreover, many sensors and complex calculations, such as monitoring a module voltage of batteries, and simultaneously considering influence of the internal resistance and influence of secular degradation, are conventionally necessary for estimating the level of the SOC. Therefore, there has been a problem that degrees of degradation (namely, a cycle damage number and a calendar damage number) with respect to the cycle life and the calendar life, which are the major damage factors of a battery, cannot be simply calculated. It should be noted that this problem can occur not only to the batteries but generally to electricity storage devices including capacitors and the batteries.

### SUMMARY OF THE INVENTION

The present invention has been made in view of above-mentioned problems, and therefore has an object to provide a degradation monitoring method and a degradation monitoring device for an electricity storage device, which are capable of simply calculating the degree of degradation with respect to the cycle life and the calendar life of the electricity storage device.

According to the present invention, there is provided a degradation monitoring method for an energy storage device, which is carried out by a degradation monitoring device including a damage calculation unit, including: acquiring, by the damage calculation unit, a charge current value, a charge period, and a representative temperature of the electricity storage device while the electricity storage device is being charged, calculating a cycle damage number for representative temperature based on acquired values of the charge current value, the charge period, and the representative temperature, and integrating the cycle damage number for representative temperature; and acquiring, by the damage calculation unit, a representative temperature of the electricity storage device in at least an operation state out of the operation state and a storage state, and an elapsed period at the representative temperature, calculating a calendar damage number based on acquired values of the representative temperature and the elapsed period, and integrating the calendar damage number.

According to the present invention, there is also provided a degradation monitoring device for an electricity storage device, including a damage calculation unit, the damage calculation unit including: a cycle damage calculation unit for acquiring a charge current value, a charge period, and a representative temperature of the electricity storage device while the electricity storage device is being charged, a representative temperature of the electricity storage device in at least an operation state out of the operation state and a storage state, and an elapsed period at the representative temperature, and calculating a cycle damage number for representative temperature based on the charge current value, the charge period, and the representative temperature of the electricity storage device while the electricity storage device is being charged; and a calendar damage calculation unit for calculating a calendar damage number based on the representative temperature of the electricity storage device in at least the operation state, and the elapsed period at the representative temperature.

According to the degradation monitoring method and the degradation monitoring device for an energy storage device, the damage calculation unit calculates the cycle damage number based on the charge current value, the charge period, and the representative temperature of the electricity storage device while the electricity storage device is being charged, to thereby calculate the cycle damage integrated value; and calculates a calendar damage number based on the representative temperature of the electricity storage device in at least the operation state, and the elapsed period at the representative temperature, to thereby calculate the calendar damage integrated value. Therefore, the degree of the degradation with respect to the cycle life and the calendar life of the electricity storage device may be calculated simply.

### BRIEF DESCRIPTION OF THE DRAWINGS

In the accompanying drawings:

FIG. 1 is a block diagram illustrating a monitoring device for an electricity storage device, according to a first embodiment of the present invention;

FIG. 2 is an explanatory diagram illustrating cycle damage calculation processing and calendar damage calculation processing;

FIG. 3 is a chart illustrating a difference in damage depending on the type of batteries described in Sasaki Masakazu, Proceedings of 2008 Annual Conference of Institute of Electrical Engineers of Japan, Industry Applications Society, 2-04-4, II-205 (2008);

FIG. 4 is an explanatory diagram illustrating a battery operation example on a battery-leasing electric vehicle according to a second embodiment of the present invention;

FIG. 5 is an explanatory diagram illustrating an example of operating a battery for battery reuse according to a third embodiment of the present invention;

FIG. 6 is a block diagram illustrating a monitoring device for an electricity storage device, according to a fourth embodiment of the present invention;

FIG. 7 is an explanatory diagram illustrating an example of replacement of a battery portion on a battery-leasing electric vehicle according to a fifth embodiment of the present invention;

FIG. 8 is an explanatory diagram illustrating an example of operating a battery for battery reuse according to a sixth embodiment of the present invention; and

FIG. 9 is a block diagram illustrating a monitoring device for an electricity storage device, according to a seventh embodiment of the present invention.

### DETAILED DESCRIPTION OF THE PREFERRED EMBODIMENTS

A description is now given of embodiments of the present invention referring to the drawings.

### First Embodiment

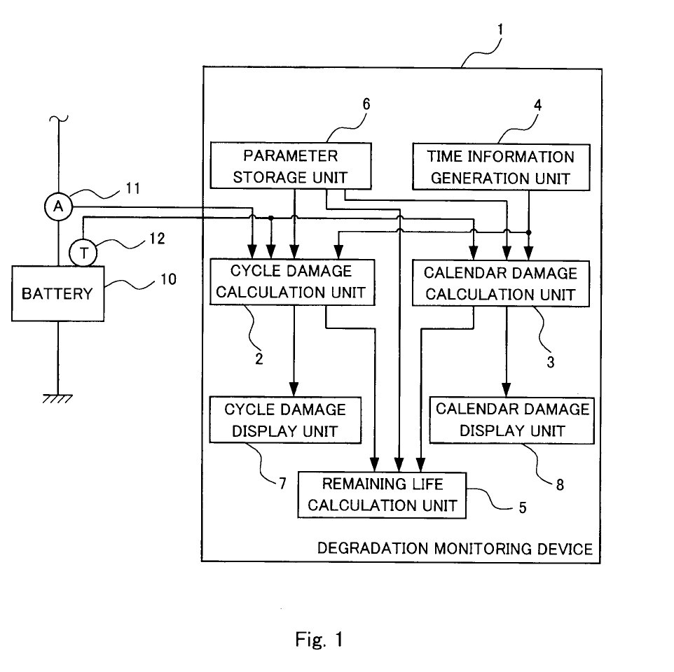

FIG. 1 is a block diagram illustrating a monitoring device for an electricity storage device, according to a first embodiment of the present invention.

In FIG. 1, a degradation monitoring device (damage recording device) 1 includes a cycle damage calculation unit 2 for carrying out cycle damage calculation processing, a calendar damage calculation unit 3 for carrying out calendar damage calculation processing, a time information generation unit 4 for generating time information, a remaining life calculation unit 5 for carrying out remaining life calculation of a battery 10, a parameter storing unit 6 for storing various coefficients for calculation in advance, a cycle damage display unit 7 for displaying a cycle damage integrated value (accumulated value), and a calendar damage display unit 8 for displaying a calendar damage integrated value (accumulated value).

A current sensor 11 serving as current detection means is provided on input/output lines connected to terminals of the battery 10 serving as an electricity storage device. A temperature sensor 12 serving as temperature detection means constructed by a thermocouple or the like is provided on a container surface of the battery 10. Output signals from the current sensor 11 and the temperature sensor 12 are sent to the degradation monitoring device 1.

The cycle damage calculation unit 2 monitors a charge/discharge current of the battery 10 via the current sensor 11. Note that, the current sensor 11 may be omitted, and the degradation monitoring device 1 may monitor the charge/discharge current of the battery 10 using a current measurement value from a battery charge/discharge control device (not shown), a DC/DC converter (not shown), or the like. The cycle damage calculation unit 2 can detect the start and end of charge of the battery 10 according to the direction of the charge/discharge current of the battery 10. Moreover, the cycle damage calculation unit 2 measures a charge period from the charge start to the charge end based on the time information from the time information generation unit 4.

The cycle damage calculation unit 2 further carries out the cycle damage calculation processing when the charge end of the battery 10 is detected. Moreover, the cycle damage calculation unit 2 calculates a cycle damage integrated value by integrating (accumulating) the cycle damage number obtained by the cycle damage calculation processing. The cycle damage calculation unit 2 then displays the calculated cycle damage integrated value on the cycle damage display unit 7.

The calendar damage calculation unit 3 monitors, via the temperature sensor 12, a representative temperature of the battery 10 in at least an operation state out of the operation state and a storage state. Moreover, when the calendar damage calculation unit 3 detects a change in representative temperature of the battery 10, the calendar damage calculation unit 3 measures an elapsed period at the representative temperature before the change based on the time information from the time information generation unit 4.

The calendar damage calculation unit 3 further carries out the calendar damage calculation processing when the change in representative temperature of the battery 10 is detected. Namely, the calendar damage calculation unit 3 carries out the calendar damage calculation processing each time the representative temperature of the battery 10 changes. Moreover, the calendar damage calculation unit 3 calculates a calendar damage integrated value by integrating (accumulating) the calendar damage number obtained by the calendar damage calculation processing. The calendar damage calculation unit 3 then displays the calculated calendar damage integrated value on the calendar damage display unit 8.

The cycle damage display unit 7 and the calendar damage display unit 8 are mechanical dial indicators (analog indicators) which are used for an oddmeter or the like of a motor vehicle, for example, and in which reset of a display content is inhibited. The cycle damage calculation unit 2 and the calendar damage calculation unit 3 change the display contents of the cycle damage display unit 7 and the calendar damage display unit 8 by driving a motor used for rotating the mechanical display. It should be noted that digital displays may be used as the cycle damage display unit 7 and the calendar damage display unit 8. Reset of the display content is preferably inhibited in this case.

On this occasion, each of the functional blocks 2 to 6 of the degradation monitoring device 1 can be realized by a microcomputer having arithmetic processing means (such as CPU), storage means (such as ROM and RAM), and input/output means. Programs for realizing the functions of the cycle damage calculation unit 2, the calendar damage calculation unit 3, the time information generation unit 4, and the remaining life calculation unit 5 are stored in the storage means of the microcomputer of the degradation monitoring device 1. Note that, the respective functional blocks of the cycle damage calculation unit 2, the calendar damage calculation unit 3, and the remaining life calculation unit 5 can be realized also by a plurality of independent microcomputers.

Moreover, the microcomputer, the cycle damage display unit 7, and the calendar damage display unit 8 of the degradation monitoring device 1 may be stored in a sealed-structure case (not shown) integrally attached to the battery 10 for preventing the display contents of the damage from being falsified. As a result, the display contents of the cycle damage display unit 7 and the calendar damage display unit 8 are increased in reliability, and if the battery 10 is used around or the battery 10 is reused as a output smoothing battery for a solar cell, the remaining life of the battery 10 can be determined from the display contents of the cycle damage display unit 7 and the calendar damage display unit 8, and the residual value of the battery 10 can be objectively determined.

The degradation monitoring device 1 itself can be integrated and sealed into an electric power conversion machine, namely a DC/DC converter and an inverter. If an ammeter is integrated into the DC/DC converter or the inverter, a current value thereof can be used for calculating damages described later.

Moreover, a power supply for the degradation monitoring device 1 may be the battery 10, an external power supply such as commercial power supply, or both thereof. If the degradation monitoring device 1 can be supplied with electric power in a state in which the battery 10 is removed from the electricity storage system, the degree of the degradation of the battery 10 can always be monitored independently of the operation state/storage state of the battery 10.

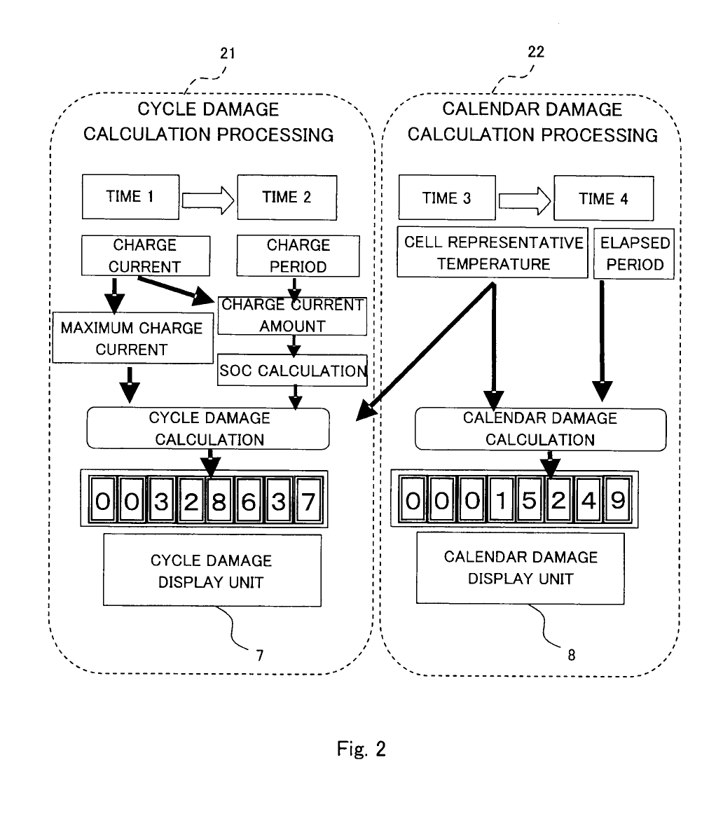

A more specific description is now given of the cycle damage calculation processing and the calendar damage calculation processing. FIG. 2 is an explanatory diagram illustrating the cycle damage calculation processing and the calendar damage calculation processing. In FIG. 2, a cycle damage calculation processing step 21 is carried out by the cycle damage calculation unit 2 when the charge of the battery is finished. A time 1 in FIG. 2 is a charge start time, and a time 2 in FIG. 2 is a charge end time. The cycle damage calculation unit 2 obtains a charge period from the charge start time to the charge end time, and uses this charge period for the cycle damage calculation processing.

The cycle damage calculation unit 2 carries out the cycle damage calculation processing using a general equation represented by the following equation 1.

Y1=SOCE*(1+|Temp−25|/10)*I/B (Equation 1)

where Y1: cycle damage number, SOCE: state of charge [SOC] at the charge end (%), Temp: representative temperature of the battery (° C.), I: maximum charge current during charge (A), and B: maximum permissible current of the battery (A).

In the equation 1, the SOCE (state of charge end) is a state of charge [SOC] at the end of charge (%). For a charge from SOC 50% to SOC 70%, for example, the SOCE is 70, and is used for the calculation of the equation 1. SOC (state of charge) (%) is an important index for a lithium-ion battery, and is always monitored in many cases. As a method of recognizing the SOC, though a general method calculates the SOC (%) by integrating the charge current and the discharge current to recognize the current quantity (Ah), a method of simply calculating the SOC (%) from an average voltage is often used. The SOC (%) calculated as described above may be used for the equation 1.

Moreover, “(1+|Temp−25|/10)” in the equation 1 is a correction to influence by the temperature. This correction is a correction to double the damage number as the temperature increases by 10° C. with respect to 25° C. Therefore, if the charge is carried out while the battery representative temperature is 45° C., the damage number becomes three times that at 25° C. Moreover, the damage number is five times for the charge at −15° C. with respect to that at 25° C. based on the theory that the damage number increases at low temperature.

Further, “I/B” in the equation 1 is a correction for the current value (C rate). I(A) is an actually measured value of the current, and the maximum current during the charge. “I/B” cannot be exceeded with respect to B (maximum permissible current (A) of the battery), and is 1.0 at maximum. According to this correction, the damage number is halved for a charge with a current value that is half of the maximum permissible current (A) of the battery.

On this occasion, it is known that the damage by charge is three times as much as damage by discharge in the lithium-ion battery, but there is not such a large difference for the lead-acid battery and the nickel-metal hydride battery. The equation 1 considers only the charge current for the calculation, and does not consider the discharge current for the calculation, which does not pose a problem. The degree of degradation and the remaining life can be calculated in a manner that, for the lithium-ion battery, a cycle damage number that is 1.3 times the cycle damage number for the charge is considered as a cycle damage number for the charge/discharge, and for other batteries, the cycle damage number is multiplied by a coefficient according to characteristics of a battery.

Then, the calendar damage calculation processing step 22 is carried out by the calendar damage calculation unit 3 when the representative temperature of the battery changes (in at least the operation state out of the operation state and the storage state). A time 3 in FIG. 2 is a temperature change reference time, and a time 4 in FIG. 2 is a temperature change detection time. The calendar damage calculation unit 3 obtains an elapsed period from the temperature change reference time and the temperature change detection time, and uses this charge period for the calendar damage calculation processing. Moreover, the calendar damage calculation unit 3 carries out the calendar damage calculation processing using a general equation represented by the following equation 2.

Y2=Time*2exp(Max(0,(Temp−25)/10)) (Equation 2)

where Y2: calendar damage number, Time: elapsed period (hr), and Temp: representative temperature of the battery (° C.).

The above-mentioned equation 2 is an equation for calculating the calendar damage number with an elapsed period (hr) at 25° C. being as a reference. The calendar damage number reaches 100 if 100 hours including the charge/discharge period and stop periods have elapsed at 25° C. The calendar damage number reaches 400 if 100 hours including the charge/discharge period and stop periods have elapsed at 45° C., which is four times as large as that at 25° C. The degree of degradation of the battery for storage at a low temperature less than 25° C. is basically similar to the degree of degradation at 25° C., and hence the calendar damage number when the representative temperature is less than 25° C. is set to that at 25° C.

The calendar damage depends on the SOC (%) for the lithium-ion battery, and the damage increases as the SOC (%) increases, and is approximately proportional to the SOC (%). In other words, the damage is halved at the same temperature at the SOC 50% compared with the SOC 100%. Therefore, when the equation 2 is intended to be used for a lithium-ion battery, it is preferred to change to the equation obtained by multiplying the equation 2 by SOC/100.

Moreover, though it is known that the storage degradation, namely the calendar life is proportional to the square root (√) of time, the calendar damage number is in a linear relationship with time in the equation 2. In contrast to this, if the remaining life of the battery is calculated, the degree of degradation proportional to the square root (√) of the time can be expressed by taking the square root of the calendar damage number.

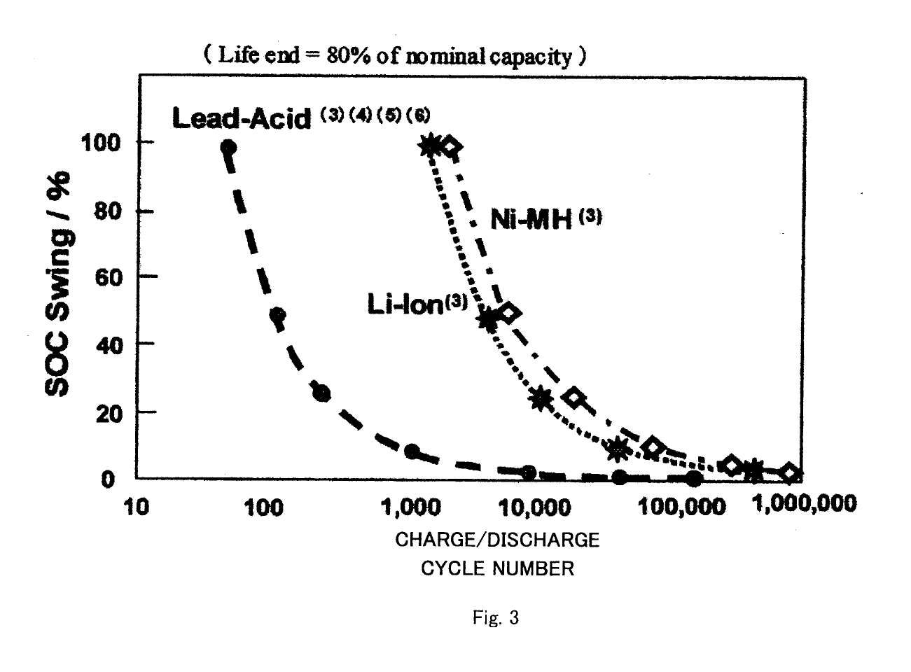

A specific description is now given of the remaining life calculation processing. FIG. 3 is a chart illustrating a difference in damage depending on the type of batteries described in Sasaki Masakazu, Proceedings of 2008 Annual Conference of Institute of Electrical Engineers of Japan, Industry Applications Society, 2-04-4, II-205 (2008). The vertical axis in FIG. 3 corresponds to SOC_Swing, namely a width (%) if the swing reciprocates to the same widths both for a depth of charge (DOC) and a depth of discharge (DOD). The horizontal axis in FIG. 3 is a charge/discharge cycle number, and represents the charge/discharge cycle number when the capacity of the battery decreases to 80%, namely at the life end.

FIG. 3 shows actual measured data for three types of batteries, the lead-acid battery, the lithium-ion battery, and the nickel-metal hydride battery. According to FIG. 3, if a charge/discharge of SOC_Swing width 100%, namely full charge/discharge with respect to the initial capacity, is repeated 100 times for the case of the lead-acid battery, for example, the capacity decreases to 80% of the initial capacity, and thus reaches the product life.

In contrast, if a charge/discharge of SOC_Swing width 10%, namely 10% of the initial capacity, is repeated 1,000 times, the capacity decreases 80% of the initial capacity. Then, the permissible cycle numbers greatly increase for the lithium-ion battery and the nickel-metal hydride battery with respect to the lead-acid battery, but the shapes of charts as actual data are exactly the same as the shape of the chart for the lead-acid battery.

The remaining life calculation processing by the remaining life calculation unit 5 of the degradation monitoring device 1 according to the first embodiment focuses on this point. The SOC_Swing width and the damage number are in the same relationship independently of the type and configuration of batteries, and the charts in FIG. 3 can be reproduced by integrating the damage number, and multiplying a coefficient dependent on the type and configuration of a battery.

Moreover, the cycle damage number can be obtained by obtaining and integrating the SOC_Swing width. By obtaining the cycles of only the charge current out of the charge/discharge cycles, the damage number can be integrated as objective data independently of the type and structure of batteries having different damage numbers for the charge and discharge, and the damage number and the remaining life can be calculated as common indices by multiplying the integrated damage number by a coefficient dependent on the type and structure of the battery.

The damage in FIG. 3 can be directly expressed by replacing SOCE*I/B in the equation 1 by the SOC_Swing width (%). It is thus preferred to replace SOCE*I/B in the equation 1 by the SOC_Swing width (%) if the SOC (%) can always be calculated and obtained to calculate the SOC_Swing width (%). However, a limit may be imposed on the calculation or the memory in obtaining the SOC_Swing width (%), and hence a simpler equation using the last SOC (%) of the charge and the maximum current I during the charge are employed for the equation 1. It is considered that the charge current is large if the SOC_Swing width (%) is large in FIG. 3, and the SOC_Swing width (%) is replaced by the product of the last SOC (%) of the charge and the maximum current I. The last SOC (%) at the end of the charge and the maximum current I can be calculated by the maximum charge current and the integration of the charge current quantity until the end of the charge, and hence the quantity of calculation always carried out decreases compared with the case in which the SOC (%) is always calculated and the SOC_Swing width (%) is obtained from the difference between the SOC (%) at the start of the charge and the SOC (%) at the end of the charge, resulting in an advantage of a simplified memory and the like. This is one of devised points of the present invention.

A description is now given of the remaining life calculation processing for the lithium-ion battery as an example. The damage number for the discharge is ⅓ of that of the charge for the lithium-ion battery. Then, it is assumed that the lithium-ion battery has the same cycle life performance as that in FIG. 3. A cycle damage number not only for the charge but also for the discharge is obtained by multiplying the equation 1 by 1.3, and the degree of degradation (%) is calculated by multiplying the resulting cycle damage number by 3.5*10exp(−4) as a cycle coefficient specific to the battery. In other words, if the full charge/discharge (SOC_Swing width: 100%) is repeated approximately 2,200 times at the maximum charge current I equal to the rated current value B at 25° C., Y1 in the equation 1 is calculated as follows.

$$\begin{matrix}Y 1 = SOCE * ( 1 + \vert Temp - 25 \vert / 10 ) * I / B * 2200 \\ = 100 * ( 1 + \vert 25 - 25 \vert / 10 ) * B / B * 2200 \\ = 220000\end{matrix}$$

The resultant obtained by multiplying Y1 by 1.3 and 3.5*10exp(−4) as the coefficient specific to the battery is 100, and 100% of the cycle life is thus reached.

Referring to the characteristic of the lithium-ion battery in FIG. 3, if the charge/discharge (SOC_Swing width: 100%) is repeated approximately 2,000 times, 100% of the cycle life is reached, and the validity of the equation 1 is clearly proven.

Y2 in the equation 2 for an elapsed period 10,000 hours at 25° C. is then calculated as follows.

$$\begin{matrix}Y 2 = Time * 2 exp ( Max ( 0 , ( Temp - 25 ) / 10 ) ) \\ = 10000 * ( 1 ) \\ = 10000\end{matrix}$$

Moreover, Y2 is calculated as follows for an elapsed period 10,000 hours at 55° C.

$$\begin{matrix}Y 2 = Time * 2 exp ( Max ( 0 , ( Temp - 25 ) / 10 ) ) \\ = 10000 * ( 8 ) \\ = 80000\end{matrix}$$

It is assumed that the lithium-ion battery is designed so that the life time is proportional to the square root (√) of time, and has a calendar life 80,000 hours at 25° C. If the root square (√) of Y2 is multiplied by 0.35 as the calendar coefficient specific to the battery, the product of the root square (√) of Y2 and the calendar coefficient specific to the battery reaches 100 after 8,000 hours at 25° C., which indicates that 100% of the calendar life is reached. The square root (√) of Y2 also reaches 100 if 10,000 hours has elapsed at 55° C., which means that the calendar life has been reached after one eighth of the period for 25° C.

Though the cycle coefficient used in the course of calculating Y1 and the calendar coefficient used in the course of calculating Y2 are each specific to the type and configuration of the battery, how much of the life remains (how much of the life is consumed) can be easily recognized using the common indices Y1 and Y2. This enables easy calculation of the remaining life of a battery.

The remaining life (%) of the battery can be represented by the following equation 3.

Y3=100−(C*Y1+D*√(Y2)) (Equation 3)

where Y3: remaining life (%), C: cycle coefficient (specific to the battery), and D: calendar coefficient (specific to the battery).

On this occasion, C=3.5*10exp(˜4) and D=0.35 for the lithium-ion battery, for example. If Y1=40,000 and Y2=10,000, the remaining life Y3 of the battery (lithium-ion battery) is obtained as follows.

$$\begin{matrix}Y 3 = 100 - ( 3.5 * 10 exp ( - 4 ) * 40000 + 0.35 * √ ( 10000 ) ) \\ = 100 - ( 14 + 35 ) \\ = 51\end{matrix}$$

It follows that the remaining life is 51%. Note that, the remaining life may be displayed in the same manner as the cycle damage integrated value and the calendar damage integrated value (a remaining life display unit may be added).

According to the above-mentioned first embodiment, the cycle damage calculation unit 2 calculates the cycle damage number based on the charge current value, the charge period, and the representative temperature of the battery 10 during the charge of the battery 10, and then calculates the cycle damage integrated value. Moreover, the calendar damage calculation unit 3 calculates the calendar damage number based on the representative temperature of the battery 10 in at least the operation state and the elapsed period at the representative temperature, and then calculates the calendar damage integrated value. This configuration enables the simple calculation of the degrees of degradation of the battery 10 for the cycle life and the calendar life. In addition, the integrated records of the damages on the battery 10 can be obtained by the simple system.

Moreover, the cycle damage calculation unit 2 monitors only the charge current out of the charge current and the discharge current, and hence the calculation can be stopped during the discharge, and the period and the calculation load imposed by the calculation of the cycle damage number can be reduced.

By the way, there has been a conventional problem that the degree of degradation of a battery cannot objectively be evaluated if the type or the configuration of batteries varies. Moreover, durability in terms of the cycle life and the calendar life greatly vary depending on the type of batteries or on component materials and structure even for the same type of batteries, such as a case that the lead-acid battery is weak in the cycle life but strong in the calendar life, while the lithium-ion battery is strong in the cycle life but weak in the calendar life. In contrast to this, according to the first embodiment, the remaining life calculation unit 5 can calculate the remaining life not from information specific to the battery such as the voltage of a cell of the battery or the state of the SOC, but from the damage numbers (common indices independent of the type and the configuration of the battery) based on the current value, the temperature, the time, and the like, and from the cycle coefficient and the calendar coefficient registered in advance. Therefore, the battery may be easily used around or reused for other applications.

### Second Embodiment

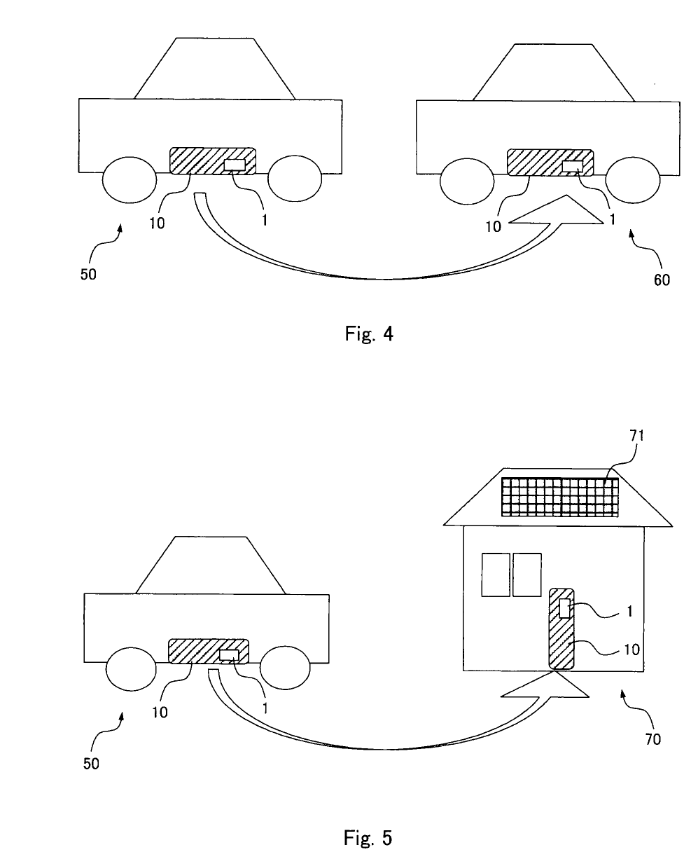

FIG. 4 is an explanatory diagram illustrating a battery operation example on a battery-leasing electric vehicle according to a second embodiment of the present invention. FIG. 4 illustrates a case in which a destination to incorporate the battery 10 is changed from an electricity storage system on an electric vehicle 50 to an electricity storage system on another electric vehicle 60. When the electricity storage system to which the battery 10 is to be incorporated is changed, the degradation monitoring device 1 attached to the battery 10 takes over the cycle damage integrated value, the calendar damage integrated value, and the remaining life in the electricity storage system before the change to the electricity storage system after the change.

As a result, the continued management of the degree of degradation of the battery 10 is enabled by the degradation monitoring device 1, and the integration of the damage numbers can be continued on the another electric vehicle 60, thereby calculating and presenting the remaining life of the battery 10 to a user.

### Third Embodiment

FIG. 5 is an explanatory diagram illustrating an example of operating a battery for battery reuse according to a third embodiment of the present invention. FIG. 5 illustrates a case in which a destination to incorporate the battery 10 is changed from an electricity storage system on the electric vehicle 50 to an electricity storage system on a solar system 70 including a solar cell panel 71. The degradation monitoring device 1 in this case also takes over the cycle damage integrated value, the calendar damage integrated value, and the remaining life in the electricity storage system before the change to the electricity storage system after the change, as in the second embodiment.

Though the usage of the battery 10 is different and the damages after the reuse greatly change in this case, the continued management of the degree of degradation of the battery 10 is enabled as in the second embodiment, and the remaining life of the battery 10 can be calculated, and can be presented to a user for the output smoothing of the solar cell panel 71 and a midnight electric power storage for household applications.

### Fourth Embodiment

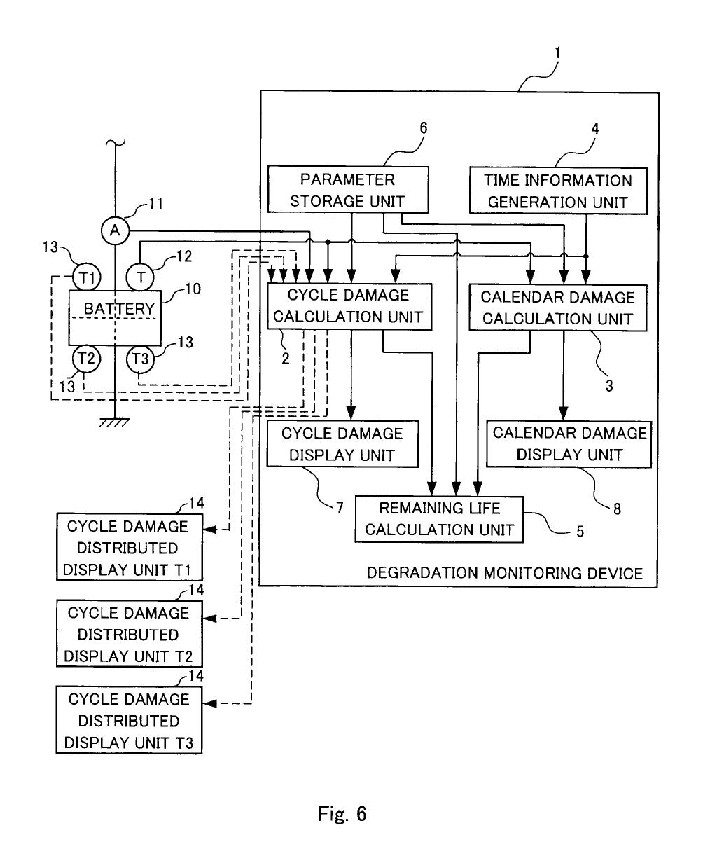

FIG. 6 is a block diagram illustrating a monitoring device for an electricity storage device, according to a fourth embodiment of the present invention. The block diagram of FIG. 6 according to the fourth embodiment is different from the block diagram of FIG. 1 according to the above-mentioned first embodiment in that distributed temperature sensors 13 provided at a plurality of locations on the electricity storage device, for measuring distributed temperatures, and cycle damage distributed display units 14 for integrating and displaying the cycle damages (for distributed temperatures) are further provided. A description is now therefore mainly given of those differences.

The distributed temperature sensors 14 according to the fourth embodiment are installed corresponding to the units of the module or block units when the electricity storage device 10 is divided and reused after the operation. The temperature sensor 12 corresponding to the representative temperature sensor may be installed on one of the units of the module or block for the reuse.

Broken lines in FIG. 6 indicate that the electricity storage device 10 is divided into four parts after the operation, exemplifying a case in which the representative temperature sensor 12 and the three distributed temperature sensors 13 are temperature sensors respectively representing the four divided units of the module or block.

If there are four units of the module or block for reuse as illustrated in FIG. 6, three of the cycle damage distributed display units 14 are used and display the integrated values of respective cycle damages (for distributed temperatures) corresponding to the three distributed temperature sensors 13. Moreover, the cycle damage display unit 7 displays the integrated value of a cycle damage corresponding to the representative temperature sensor 12. The cycle damage distributed display units 14 are then installed for the units of the module or block to be divided according to the number of the distributed temperature sensors 13 to be added.

If the electricity storage device 10 is divided and reused after the use, the cycle damage display unit 7 and the cycle damage distributed display units 14 are separated while being respectively installed on the units of the module or block for reuse. As a result, it is possible to know a past cycle damage even after the separation into units of the module or block, and further to continue the integration after the reuse. Further, it is possible to increase the reliability of the cycle damage by preventing the data from being falsified, thereby providing an effect of promoting trading according to a used price.

If the electricity storage device is used as a power supply for an electric vehicle, due to degradation of a specific module or block of the electricity storage device, the unit of the module or block may be replaced. On this occasion, the cycle damage distributed display units 14 displaying the integrated cycle damage number corresponding to the distributed temperature sensors 13 enable to clearly distinguish the newly replaced unit of the module or block from the other units of the module or block, thereby continuing the integration of the cycle damages.

It is preferred that the calendar damage be integrated and displayed for units of the module or block to be reused as in the case of the cycle damage. However, during the stop of the charge/discharge, the electricity storage device does not generate heat, and the temperature does not vary so greatly depending on the location. The calendar damage may be integrated only according to the value of the representative temperature sensor 12.

If a module or block as a unit is replaced or reused, the calendar damage integrated value integrated only according to the value of the representative sensor 12 is recorded on paper such as a repair record, and the record may be used for calculating the remaining life.

### Fifth Embodiment

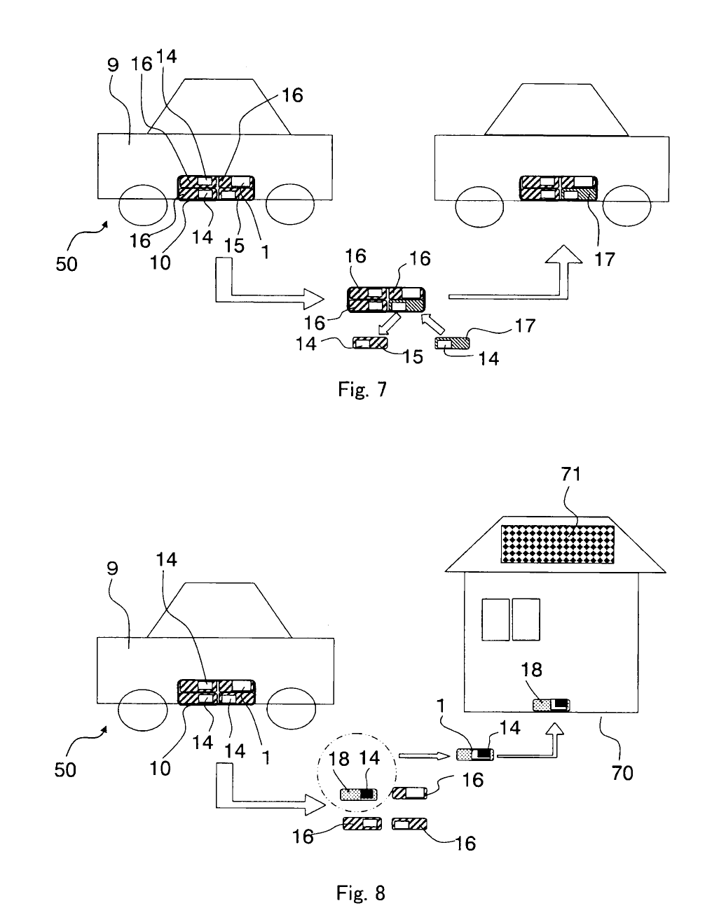

FIG. 7 is an explanatory diagram illustrating an example of replacement of a battery portion on a battery-leasing electric vehicle according to a fifth embodiment of the present invention. Referring to FIG. 7, a description is now given of a case in which a large degradation has occurred to a specific battery block 15 out of four battery blocks 16.

The fact that the large degradation has occurred to the specific battery block 15 out of the four battery blocks 16 can be detected by monitoring the cycle damage integrated value (for distributed temperatures). For example, if a cycle damage integrated value (for distributed temperatures) higher than the cycle damage integrated value (for representative temperature) by 30% is recorded, an alarm is generated, and the battery block 15 is replaced by a new or used battery block 17 having a similar cycle damage integrated value (for distributed temperatures), and the battery block 17 is reinstalled on the electric vehicle to be used.

On this occasion, a calendar damage of the replaced battery block 17, which is zero when the battery block 17 is new, or a calendar damage recorded on an electricity storage device 10 to which the battery block 17 is previously installed if the cycle damage integrated value (for distributed temperatures) thereof is similar for the used battery, is recorded in a maintenance record table. The replacement of the battery is entrusted to a specialist because of high-voltage electricity safety, and the record to the maintenance record table does not pose a problem.

Though the case in which the calendar damage is recorded only for the representative temperature sensor 12 has been described, if the calendar damage is recorded for the battery blocks 16 as units, the values thereof and the display devices are also taken over.

### Sixth Embodiment

FIG. 8 is an explanatory diagram illustrating an example of operating a battery for battery reuse according to a sixth embodiment of the present invention. FIG. 8 illustrates a case in which an electricity storage device 10 installed on an electric vehicle is taken apart into four blocks 16, and one of the four blocks 16 is used to an electricity storage system in a solar system 70 including a solar cell panel 71.

The block 16 does not include the calendar damage calculation unit 3 and the calendar damage display unit 8, and hence the cycle damage distributed display unit 14 which has carried out recording is installed on a new degradation monitoring device 1, and the degradation monitoring device 1 is then integrated. Then, the newly installed degradation monitoring device 1 takes over the cycle damage integrated value in the electricity storage system before the change to the electricity storage system after the change. For the calendar damage integrated value, the calendar damage integrated value of the degradation monitoring device 1 which has been installed on the electric vehicle is adjusted as an initial value. As a result, even the remaining life calculation can be continued.

If the block 16 carrying the degradation monitoring device 1 is used for the electricity storage system of the solar system 70, the block 16 can be directly used. Moreover, if the calendar damage is recorded for the battery block 16 as a unit, the value and the display device thereof are taken over to the newly installed degradation monitoring device 1. As a result, if the electricity storage device 10 is divided and reused, the history of the damages can be precisely taken over to a next destination of use.

### Seventh Embodiment

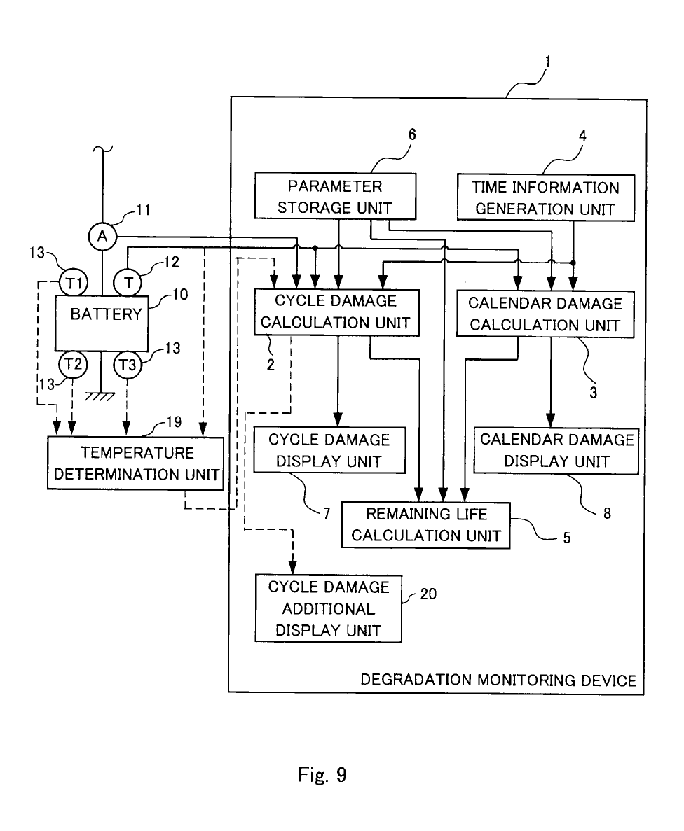

FIG. 9 is a block diagram illustrating a monitoring device for an electricity storage device, according to a seventh embodiment of the present invention. Compared with the block diagram in FIG. 1 according to the above-mentioned first embodiment, the block diagram in FIG. 9 according to the seventh embodiment is different in that the distributed temperature sensors 13 provided at a plurality of locations on the electricity storage, for measuring distributed temperatures, a temperature determination unit 19, and a cycle damage additional display unit 20 are further provided. A description therefore is now mainly given of these differences.

The temperature determination unit 19 compares the temperature detected by the temperature sensor 12 and the temperatures detected by the distributed temperature sensors 13, and selects the highest temperature. Moreover, the cycle damage additional display unit 20 calculates the cycle damage (for highest temperature) using the highest temperature selected by the temperature determination unit 19, and integrates and displays a numerical value larger than the cycle damage (for representative temperature).

The value displayed on the cycle damage additional display unit 20 may be regarded as a deviation score, and enables recognition of how much the damage number additionally increases at the highest temperature with respect to the damage number at the representative temperature.

On this occasion, the highest temperature is not always detected by a temperature sensor at a certain location. By which distributed temperature sensor 13 the highest temperature is observed varies depending on a state of use of a vehicle, the life of the battery 10, and the states of the individual battery cells.

An increase in the value displayed on the cycle damage additional display unit 20 implies that a local damage is occurring to the battery 10, and an alarm generated based on this result carries an important meaning. In other words, a battery cell having the largest damage out of battery cells serially connected determines the life performance of the overall battery 10.

An enormous data bank is necessary for recording data and secular changes of all of the distributed temperature sensors 13, and the amount of the calculation processing is enormous. In contrast, as in the seventh embodiment, it is possible to precisely recognize to what extent the local damage of the battery 10 extends by extracting only the highest temperature, and integrating the cycle damage (for highest temperature) while the calculation processing amount is restrained.

The degradation monitoring device 1 according to the seventh embodiment calculates the cycle damage number (for highest temperature) based on the charge current value, the charge period, and the highest temperature of the electricity storage device while the electricity storage device is being charged, sets the difference between the cycle damage number (for highest temperature) and the cycle damage number (for representative temperature) as the cycle damage additional value, and integrates the cycle damage additional value, thereby calculating the cycle damage additional integrated value.

The degradation monitoring device 1 according to the seventh embodiment may generate an alarm when the cycle damage additional integrated value exceeds the cycle damage integrated value by 30%, for example, thereby notifying a driver that the local damage of the battery 10 is exceeding the limit. As a result, it is possible to prevent a functional defect of the battery 10 caused by a failure of a specific battery cell, and to provide a chance to inspect the battery 10 of the vehicle, thereby preventing an accident from occurring.

Compared with the above-mentioned fourth embodiment, according to the seventh embodiment, the cycle damage distributed display units 14 can be eliminated. As a result, the number of the cycle damage display units decreases, and the amount of the cycle damage calculation decreases, resulting in an effect of low cost. Further, although the number of the temperature sensors increase by adding the distributed temperature sensors 13, the cycle damage is calculated from the highest temperature, and hence it is not necessary to increase the calculation period and the number of display units.

Moreover, an additional display for the cycle damage may be carried out for the second highest temperature in place of the highest temperature, or a similar display may be carried out for an average temperature of the highest temperature and the second highest temperature. In other words, an important point of the invention according to the seventh embodiment is to quantitatively recognize an extent of variation of the electricity storage device 10 constructed by a large number of cells and modules based on the temperature other than the representative temperature, and to generate an alarm so that a defect may be prevented from occurring.

The above description of the first to seventh embodiments is given of the calculation method of the damage focusing on the lithium-ion battery. However, the type of the electricity storage device is not limited to the lithium-ion battery, and the calculation method may also be applied to other types of batteries and capacitors such as the nickel-metal hydride battery, the lead-acid battery, and the electric double-layer capacitor. The equations 1 to 3 illustrate an example, and more realistic damage numbers and remaining life can be calculated by changing (increasing complexity and optimizing) the respective equations.

What is claimed is:

1. A degradation monitoring method for an energy storage device, which is carried out by a degradation monitoring device including a damage calculation unit, comprising:
acquiring by the damage calculation unit, a charge current value, a charge period, and a representative temperature of the electricity storage device while the electricity storage device is being charged, calculating a cycle damage number for representative temperature based on acquired values of the charge current value, the charge period, and the representative temperature, and integrating the cycle damage number for representative temperature; and
acquiring, by the damage calculation unit, a representative temperature of the electricity storage device in at least an operation state out of the operation state and a storage state, and an elapsed period at the representative temperature, calculating a calendar damage number based on acquired values of the representative temperature and the elapsed period, and integrating the calendar damage number.

2. A degradation monitoring method for an electricity storage device according to claim 1, further comprising measuring, by the damage calculation unit, distributed temperatures at a plurality of locations of the electricity storage device in addition to the representative temperature, calculating cycle damage numbers for the distributed temperatures using the respective distributed temperatures, and integrating the cycle damage numbers for distributed temperatures for the respective distributed temperatures.

3. A degradation monitoring method for an electricity storage device according to claim 1, further comprising measuring, by the damage calculation unit, distributed temperatures at a plurality of locations of the electricity storage device in addition to the representative temperature, setting a highest temperature out of the distributed temperatures as highest temperature, obtaining a cycle damage number for highest temperature using the highest temperature, calculating a difference between the cycle damage number for highest temperature and the cycle damage number for representative temperature as a cycle damage additional number, and integrating the cycle damage additional number.

4. A degradation monitoring method for an electricity storage device according to claim 1, wherein when an electricity storage system which is a destination to incorporate the electricity storage device is changed, a cycle damage integrated value obtained by integrating the cycle damage number for representative temperature and a calendar damage integrated value obtained by integrating the calendar damage number in the electricity storage system before the change are taken over to the electricity storage system after the change.

5. A degradation monitoring method for an electricity storage device according to claim 1, wherein the cycle damage number corresponding to an acquired temperature is calculated by the following equation:
Y1=SOCE*(1+|Temp−25|/10)*I/B
where Y1: cycle damage number, SOCE: charge state at the end of charge (%), Temp: one of the representative temperature, the distributed temperatures, and the highest temperature of the electricity storage device (° C.), I: charge current (A), and B: permissible maximum current of the electricity storage device (A).

6. A degradation monitoring method for an electricity storage device according to claim 1, wherein the calendar damage number is calculated by the following equation:
Y2=Time*2exp(Max(0,(Temp−25)/10))
where Y2: calendar damage number, Time: elapsed period (hr), and Temp: representative temperature of the electricity storage device (° C.).

7. A degradation monitoring method for an electricity storage device according to claim 1, further comprising calculating, by the damage calculation unit, a remaining life of the electricity storage device using the cycle damage number for representative temperature, the calendar damage number, and a coefficient registered in advance and specific to the electricity storage device.

8. A degradation monitoring method for an electricity storage device according to claim 7, wherein the remaining life of the electricity storage device is calculated by the following equation:
Y3=100−(C*Y1+D*√(Y2))
where Y3: remaining life (%), C: cycle coefficient (specific to the electricity storage device), and D: calendar coefficient (specific to the electricity storage device).

9. A degradation monitoring device for an electricity storage device, comprising a damage calculation unit,
the damage calculation unit including:
a cycle damage calculation unit for acquiring a charge current value, a charge period, and a representative temperature of the electricity storage device while the electricity storage device is being charged, a representative temperature of the electricity storage device in at least an operation state out of the operation state and a storage state, and an elapsed period at the representative temperature, and calculating a cycle damage number for representative temperature based on the charge current value, the charge period, and the representative temperature of the electricity storage device while the electricity storage device is being charged; and
a calendar damage calculation unit for calculating a calendar damage number based on the representative temperature of the electricity storage device in at least the operation state, and the elapsed period at the representative temperature.

10. A degradation monitoring device for an electricity storage device according to claim 9, wherein the cycle damage calculation unit further calculates cycle damage numbers for distributed temperatures, for respective distributed temperatures at a plurality of locations of the electricity storage device based on the charge current value, the charge period, and the distributed temperatures while the electricity storage device is being charged.

11. A degradation monitoring device for an electricity storage device according to claim 10, wherein the cycle damage calculation unit integrates respectively the cycle damage numbers for distributed temperatures and the cycle damage number for representative temperatures, and outputs an alarm when a ratio of an integrated value of the cycle damage numbers for distributed temperatures to an integrated value of the cycle damage number for representative temperature exceeds a first predetermined ratio.

12. A degradation monitoring device for an electricity storage device according to claim 9, wherein the cycle damage calculation unit sets a highest temperature out of the distributed temperatures at the plurality of locations of the electricity storage device as highest temperature based on the distributed temperatures, calculates the cycle damage number for highest temperature based on the charge current value, the charge period, and the highest temperature of the electricity storage device while the electricity storage device is being charged, and further calculates a difference between the cycle damage number for highest temperature and the cycle damage number for representative temperature as a cycle damage additional value.

13. A degradation monitoring device for an electricity storage device according to claim 12, wherein the cycle damage calculation unit integrates respectively the cycle damage additional value and the cycle damage number for representative temperature, and outputs an alarm when a ratio of an integrated value of the cycle damage additional value to an integrated value of the cycle damage number for representative temperature exceeds a second predetermined ratio.

14. A degradation monitoring device for an electricity storage device according to claim 9, further comprising at least one of:
a cycle damage display unit for integrating the cycle damage number for representative temperature calculated by the cycle damage calculation unit, and displaying the integrated cycle damage number for representative temperature;
a cycle damage distributed display unit for integrating the cycle damage numbers for distributed temperatures calculated by the cycle damage calculation unit, and displaying the integrated cycle damage numbers for distributed temperatures;
a cycle damage additional display unit for integrating the cycle damage additional value calculated by the cycle damage calculation unit, and displaying the integrated cycle damage additional value; and
a calendar damage display unit for integrating the calendar damage number calculated by the calendar damage calculation unit, and displaying the integrated calendar damage number.

15. A degradation monitoring device for an electricity storage device according to claim 14, wherein the at least one of the cycle damage display unit, the cycle damage distributed display unit, the cycle damage additional display unit, and the calendar damage display unit is stored in a sealed-structure case temporarily attached to the electricity storage device, and provides a dial-type display structured which is mechanically incapable of being turned inversely.

16. A degradation monitoring device for an electricity storage device according to claim 14, wherein the cycle damage distributed display unit is integrated to each of dividable units of the electricity storage device.

17. A degradation monitoring method for an electricity storage device according to claim 9, further comprising a remaining life calculation unit for calculating a remaining life of the electricity storage device using the cycle damage number for representative temperature calculated by the cycle damage calculation unit, the calendar damage number calculated by the calendar damage calculation unit, and a coefficient registered in advance and specific to the electricity storage device.
